(19) United States
(12) Patent Application Publication
(10) Pub. No.: US 2010/0294433 A1
(43) Pub. Date: Nov. 25, 2010

(54) PLASMA PROCESSING APPARATUS

(76) Inventor: Nan Jianhui, Beijing (CN)

Correspondence Address: EDWARDS ANGELL PALMER & DODGE LLP, P.O. BOX 55874, BOSTON, MA, 02205, US

(21) Appl. No.: 12/811,628

(22) PCT Filed: Dec. 31, 2008
(86) PCT No.: PCT/CN2008/073884

§ 371 Date: Jul. 2, 2010

(30) Foreign Application Priority Data
Jan. 4, 2008 (CN) 200810055657.2

(51) Int. Cl. C23F 1/08; C23C 16/00

(52) U.S. Cl. 156/345.48; 118/723 I

(57) ABSTRACT

A plasma processing apparatus, comprising: a RF driving electrode (25) and a passive electrode (22) mounted face to face; a first grounded ring (23) surrounding the passive electrode (22) and insulated from it, a second grounded ring (26) surrounding the RF driving electrode (25) and insulated from it; the RF driving electrode (25) is connected with a first RF source (271) and a second RF source (272) respectively; a first impedance adjusting element is connected in series between the passive electrode (22) and the ground. The plasma processing apparatus overcomes a shortcoming that plasma energy can only be changed over among several certain isolated values, and thus technical processes with different plasma density requirements can be realized in one and the same reaction chamber.

### FIELD OF THE INVENTION

The invention relates to the field of microelectronics technologies, especially to a plasma processing apparatus.

### BACKGROUND OF THE INVENTION

A plasma processing apparatus is a processing equipment widely used in the semiconductor manufacturing field.

Reference could be made to FIG. 1 which is a schematic diagram of a structure of a common plasma processing apparatus.

The plasma processing apparatus usually comprises a shell (for which no reference sign is shown), in which there is a reaction chamber 11. The top of the reaction chamber 11 is provided with a passive electrode 12 and a top grounded ring 13 surrounding the passive electrode 12, which are insulated from each other by a first insulating ring 141. The bottom of the reaction chamber 11 is provided with a radio frequency (RF) driving electrode 15 and a bottom grounded ring 16 surrounding the RF driving electrode 15, which are insulated from each other by a second insulating ring 142. The RF driving electrode 15 is connected with a first RF source 171 and a second RF source 172 respectively; the first RF source has a lower frequency, e.g. 2 MHZ, and the second RF source 172 has a higher frequency, e.g. 60 MHz.

The passive electrode 12 is grounded, and an adjusting switch 121 is connected in series between the passive electrode 12 and the ground. Through the adjusting switch 12, the passive electrode 12 can be selected to connect in series with one of a low-pass filter 181, a high-pass filter 182 and a super low-pass filter 183; or the passive electrode 12 can be selected to be grounded directly through a bypass 184.

In the operation of the plasma processing apparatus, a workpiece (which usually comprises a wafer and other workpieces having the same processing principle as the wafer; the meaning of workpieces illustrated below is the same) is placed on the bottom of the reaction chamber 11, and a vacuum state is produced and hold in the reaction chamber 11 by a vacuum production equipment such as a molecule pump (not shown in the figure). In this state, process gas is delivered into the reaction chamber 11 via a gas input device (not shown in the figure), and an appropriate RF voltage is input between the passive electrode 12 and the RF driving electrode 15 by the first RF source 171 and the second RF source 172 to activate the process gas and then to produce and hold a plasma environment with an appropriate density and energy on the surface of the workpiece. Due to the fact that plasma has a strong ability to etch and deposit, the physical and chemical reactions such as etch and deposition will occur between plasma and the workpiece so as to achieve an etch pattern or a deposition layer as required. By-product of the physical and chemical reactions mentioned above is pumped out of the reaction chamber 11 by the vacuum production device. Respective flow paths of the RF current are schematically shown by curves with arrows in the FIG. 1.

As well known, different particular technical processes have different requirements to energies and densities of plasma in the reaction chamber. In order to increase adaptability of the plasma processing apparatus, that is, in order to achieve different specific technical processes in one and the same plasma processing apparatus, it is required that the plasma energy and the plasma density can be adjusted conveniently and effectively, it is preferable to adjust them separately.

In a dual RF system, RF current with a higher frequency mainly influences the density of plasma in the reaction chamber; RF current with a lower frequency mainly influences the plasma energy in the reaction chamber. So, the adjustment of the plasma energy can be achieved by the first RF source 171; the adjustment of the plasma density can be achieved by the second RF source 172. Particular frequencies of the two RF source are determined according to the prior art, which will not be described any more here.

However, due to the coupling between the first RF source 171 and the second RF source 172, it is difficult to control the plasma energy and the plasma density individually.

In order to solve the problem mentioned above, different filter circuits are selected by the adjusting switch 121 so as to prevent the RF current of at least one of the first RF source 171 and the second RF source 172 from flowing through the passive electrode 12; the top grounded ring 13 and the bottom grounded ring 16 can provide a return path for the RF current prevented by the filter circuit. So, decoupling between the first RF source 171 and the second RF source 172 can be achieved preliminarily, which achieves individual controls of the plasma energy and the plasma density to a certain extent.

In addition, the plasma processing apparatus can adjust the plasma density in its reaction chamber preliminarily.

The plasma density in the reaction chamber 11 can be changed by changing a bias voltage at the RF driving electrode 15; the above mentioned bias voltage can be changed notably by changing an effective area ratio of the passive electrode 12 to the RF driving electrode 15; the above mentioned effective area ratio can be obtained by adjusting the current flowing through the passive electrode 12.

The adjusting switch 121 in the above mentioned technology can select four different paths, so that four different technical processes can be adapted. In one particular path, the RF current of the first RF source 171 or the second RF source 172 flows through the passive electrode 12 or doesn't flow through the passive electrode 12. So, the adjusting switch 121 can change the RF current flowing through the passive electrode 12 so as to change the effective area ration of the passive electrode 12 to the RF driving electrode 15, along with which the bias voltage at the RF driving electrode 15 will change. Thus, the plasma density can be adjusted by the adjusting switch 121.

However, some drawbacks as follows exist in the plasma processing apparatus of the above mentioned technology.

Since the top grounded ring 13 and the bottom grounded ring 16 are grounded directly, no matter what kind of filter circuit is specifically selected by the adjusting switch 121, both of the top grounded ring 13 and the bottom grounded ring 16 can provide a return path for the RF current of the first RF source 171 and the second RF source 172, which results in forming a common RF path.

Therefore, the desirable effect of decoupling of the plasma processing apparatus cannot be obtained.

It is more important that it is difficult for the plasma processing apparatus of the above mentioned technology to adjust the plasma energy effectively, so that it is difficult to adapt to requirements of different technical processes.

As mentioned above, in the prior technology, the RF current is allowed to or prohibited to flow through the passive electrode 12 by changing the pass band of the filter circuit. Obviously, such manner of changing the RF current determines that the RF current of the first RF source 171 or the second RF source 172 can either flow through the passive electrode 12 at a certain specific value, or doesn't flow through the passive electrode 12. So, such manner can only adjust the RF current between zero and the specific value, and then the effective area ratio of the passive electrode 12 to the RF driving electrode 15 can only be changed between a higher value and a lower value. That is, such manner can only adjust the above effective area ratio between two isolated values.

Therefore, the plasma processing apparatus in the above technology can only satisfy requirements of a few technical processes and cannot adjust the plasma density in a large range. The adaptability thereof thus is poor and cannot satisfy requirements of many technical processes.

So, problems that require the persons skilled in the art to solve now are how to effectively adjust the plasma density in the plasma processing apparatus so as to satisfy requirements of many technical processes, and how to achieve a more complete decoupling of different RF currents.

### SUMMARY

An object of the present invention is to provide a plasma processing apparatus, in a reaction chamber of which plasma energy can be adjusted in a large range, so that many different technical process requirements can be satisfied.

In order to solve the above problem, the present invention provides a plasma processing apparatus, comprising: a RF driving electrode and a passive electrode mounted face to face; a first grounded ring surrounding the passive electrode and insulated from the passive electrode, a second grounded ring surrounding the RF driving electrode and insulated from the RF driving electrode; the RF driving electrode is connected with a first RF source and a second RF source respectively; a first impedance adjusting element is connected in series between the passive electrode and the ground.

Preferably, impedance of the first impedance adjusting element is continuously adjustable.

Preferably, the first impedance adjusting element is a first variable resistor R1; a first filter circuit connected in series with the first variable resistor R1 is provided between the passive electrode and the ground; a pass band of the first filter circuit is adjustable, so as to select RF current of at least one of the first RF source and the second RF source to flow through, or select neither of RF current of the first RF source and the second RF source to flow through.

Preferably, the first filter circuit comprises a first branch circuit consisting of a first variable capacitor C1 and a first inductor L1 connected in series, and a second branch circuit consisting of a second variable capacitor C2 and a second inductor L2 connected in series; the first branch circuit is parallel connected with the second branch circuit.

Preferably, a second impedance adjusting element is connected in series between the ground and at least one of the first grounded ring and the second grounded ring.

Preferably, impedance of the second impedance adjusting element is continuously adjustable.

Preferably, the second impedance adjusting element is a second variable resistor R2; a second filter circuit is provided between the ground and the first grounded ring and/or the second grounded ring; the second filter circuit is connected with the second variable resistor R2 in series, and a pass band of the second filter circuit is adjustable so as to select RF current of at least one of the first RF source and the second RF source to flow through, or select neither of RF current of the first RF source and the second RF source to flow through.

Preferably, the second filter circuit comprises a third branch circuit consisting of a third variable capacitor C3 and a third inductor L3 connected in series, and a fourth branch circuit consisting of a fourth variable capacitor C4 and a fourth inductor L4 connected in series; the third branch circuit and the fourth branch circuit are connected in parallel.

Preferably, the plasma processing apparatus is a plasma etching apparatus.

Preferably, the plasma processing apparatus is a plasma deposition apparatus.

As mentioned above, the technology described in the background art allows RF current to flow through the passive electrode or prevents RF current from flowing through the passive electrode, by changing the band pass of the filter circuit, so as to switch among different plasma energies.

Different from this, the plasma processing apparatus provided by the present invention applies a completely different idea to adjust the plasma energy in the reaction chamber. That is, the present invention changes current flowing through the passive electrode by adjusting impedance of the loop to which the passive electrode belongs (realized by adjusting the resistance of the impedance adjusting element), so as to change the plasma energy in the chamber reaction. The new idea provided by the present invention can adjust the magnitude of RF current in the passive electrode in a larger range. So, the plasma processing apparatus provided by the present invention overcomes the above mentioned shortcoming that the plasma energy can only be switched among some certain isolated values, and can realize more technical processes with different plasma density requirements in one and the same reaction chamber, so that adaptability of the plasma processing apparatus is improved greatly.

### BRIEF DESCRIPTION OF THE DRAWINGS

FIG. 1 is a schematic diagram of a structure of a common plasma processing equipment;

FIG. 2 is a schematic diagram of a structure of a plasma processing apparatus according to a first embodiment of the present invention;

FIG. 3 is a schematic diagram of a structure of a particular embodiment of a third filter circuit in FIG. 2;

FIG. 4 is a schematic diagram of a structure of a plasma processing apparatus according to a second embodiment of the present invention;

FIG. 5 is a schematic diagram of a structure of a plasma processing apparatus according to a third embodiment of the present invention; and

FIG. 6 is a schematic diagram of a structure of a plasma processing apparatus according to a fourth embodiment of the present invention.

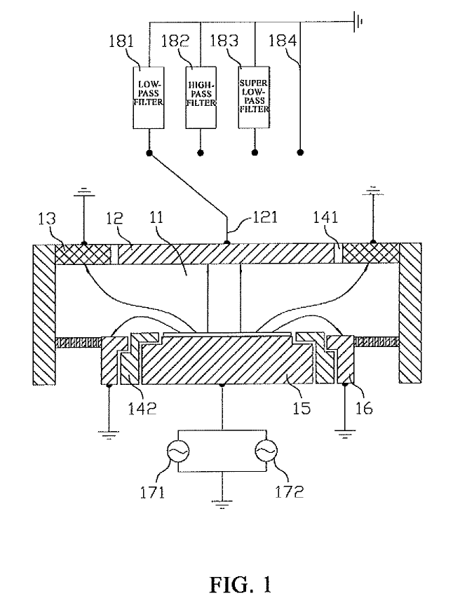

### DETAILED DESCRIPTION OF THE PREFERRED EMBODIMENT

The object of the present invention is to provide a plasma processing apparatus, wherein the plasma energy in a reaction chamber of the plasma processing apparatus can be adjusted in a large range so that requirements of many different technical processes can be satisfied.

In order that the persons skilled in the art could understand technical solutions of the invention better, further detailed description is made to the invention in connection with the figures and specific embodiments.

In most common plasma processing apparatuses, a RF driving electrode is provided on the bottom of its reaction chamber and a passive electrode is provided on the top of the reaction chamber; of course, it is possible to exchange positions of the RF driving electrode and the passive electrode, that is, the RE driving electrode is provided on the top of the reaction chamber and the passive electrode is provided on the bottom of the reaction chamber.

In view of this, the technical solutions provided by the present invention are herein illustrated only by taking an example in which the RF driving electrode is provided on the bottom of the reaction chamber. However, the protection scope of the present invention should comprise a particular case in which the RF driving electrode is provided on the top of the reaction chamber. Based on the contents disclosed herein, the persons skilled in the prior art can obtain the technical solution in the case that the RF driving electrode is provided on the top of the reaction chamber, without inventive labor.

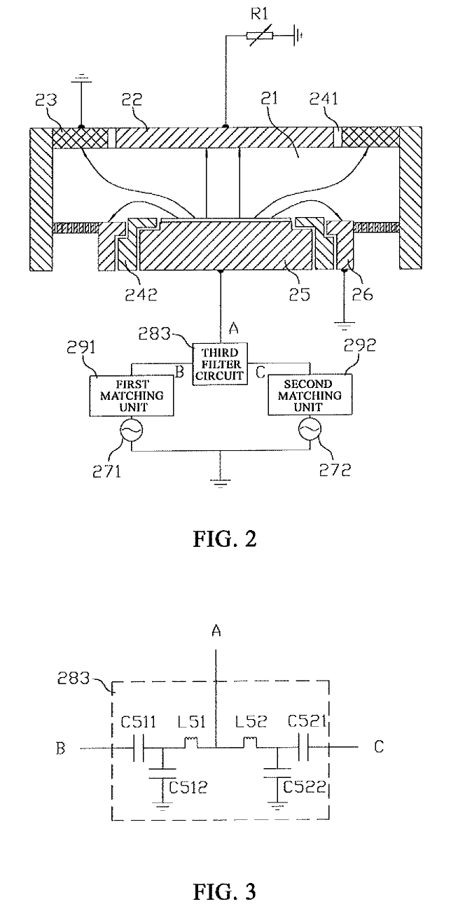

Reference is made to FIG. 2 which is a schematic view of a structure of a plasma processing apparatus according to the first embodiment of the present invention.

In the first embodiment, the plasma processing apparatus provided by the present invention comprises a shell (for which no reference sign is shown), in which there is a reaction chamber 21.

A passive electrode 22 is provided on the top of the reaction chamber 21, and the passive electrode 22 is grounded via a first variable resistor R1 as a first impedance adjusting element. A first grounded ring 23 surrounds the passive electrode 22, and the first grounded ring 23 and the passive electrode 22 insulates from each other by a first insulating ring 241. Obviously, the first grounded ring 23 should be grounded.

Obviously, the first variable resistor R1 can be replaced by other impedance adjusting elements. For example, a resistor and a capacitor can be connected in series to act as the above mentioned first impedance adjusting element.

A RF driving electrode 25 is provided on the bottom of the reaction chamber 21, and the RF driving electrode 25 is electrically connected with a first RF source 271 and a second RF source 272 respectively. The difference between the above two RF sources in frequency is great; the first RF source 271 may have a lower frequency such as 2 MHz, and the second RF source 272 has a higher frequency such as 60 MHz. A second grounded ring 26 surrounds the RF driving electrode 25, and the second grounded ring 26 and the RF driving electrode 25 are insulated from each other by a second insulating ring 242. The second grounded ring 26 should also be grounded.

It should be understood that the values of frequencies mentioned above are just illustrative and are not intended to limit the scope of the present invention.

The first RF source 271 and the second RF source 272 should be connected with a first matching unit 291 and a second matching unit 292 respectively, so as to achieve impedance matching, so that efficiencies of the above two RF sources can reach a higher level.

Reference is made to FIG. 3 which is a schematic diagram of a structure of a particular embodiment of a third filter circuit in FIG. 2.

In order to avoid a mutual interference between the first RF source 271 and the second RF source 272, a third filter circuit 283 should be connected between the above two RF sources and the RF driving electrode 25.

In particular, the third filter circuit 283 comprises three ports, Port A connected with the RF driving electrode 25, Port B connected with the first RF source 271 via the first matching unit 291, and Port C connected with the second RF source 272 via the second matching unit 292.

There are a capacitor C511 and an inductor L51 connected in series between Port A and Port B, and one terminal of a capacitor C512 is grounded and the other terminal thereof is connected between the capacitor C511 and the inductor L51. There are a capacitor C521 and an inductor L52 connected in series between Port A and Port C, one terminal of a capacitor C522 is grounded and the other terminal thereof is connected between the capacitor C521 and the inductor L52.

Pass bands of a left part and a right part of FIG. 3 can be made to be respectively adapted to the first RF source 271 and the second RF source 272 by selecting parameters of the above respective elements appropriately, so that current of the first RF source 271 cannot pass Port C and current of the second RF source 272 cannot pass Port B, thus avoiding an interference between the two RF sources.

As mentioned above, the purpose of the present invention is to adjust the plasma energy in the reaction chamber 21 effectively. And the plasma energy can be changed accordingly by changing a bias voltage at the RF driving electrode 25. As well known, the bias voltage can be changed by changing an effective area ratio of the passive electrode 22 to the RF driving electrode 25, a particular relationship between them are as follows:

V_{bias}∝(A₁/A₂)ⁿ

Wherein, V_{bias} represents the bias voltage at the RF driving electrode 25, A₁ represents an effective area of the passive electrode 22, A₂ represents an effective area of the RF driving electrode 25, the parameter n is dependent on the geometrical structure of the plasma processing apparatus and the range thereof is from 1 to 4.

The effective area ratio (A₁/A₂) can be changed by adjusting the RF current flowing through the passive electrode 22.

By referring to FIG. 2, currents of the first RF source 271 and the second RF source 272 can pass through the reaction chamber 21 along different paths from the RF driving electrode 25. The above mentioned paths comprise three paths, i.e. a path from the RF driving source 25 to the passive electrode 22, a path from the RF driving electrode 25 to the first grounded ring 23 and a path from the RF driving electrode 25 to the second grounded ring 26. An initial distribution ratio of the RF currents in the above mentioned respective paths is specifically determined by the detailed dimension of the reaction chamber 21.

Impedances of the above mentioned respective paths can be adjusted by changing the resistance of the first variable resistor R1, so that the RF currents will be redistributed on the basis of the initial distribution ratio.

When plasma having higher energy is needed in the reaction chamber 21, for example when a via hole or other patterns with a higher aspect ratio are to be etched in the surface of the workpiece, the resistance of the first variable resistor R1 can be reduced, then the impedance of the RF current loop where the passive electrode 22 is located is reduced and thus the current thereof will increase. So, the effective area ratio of the passive electrode 22 to the RF driving electrode 25 (A₁/A₂) and the bias voltage at the RF driving electrode 25 will increase accordingly, thus the plasma energy in the reaction chamber will be increased.

Obviously, when the value of the resistance of the first variable resistor R1 is zero, the plasma energy in the reaction chamber 21 can reach a maximum value (when other factors are not considered; influence of other factors on the plasma energy are not considered hereafter either).

When plasma having lower energy is needed in the reaction chamber 21, for example when a porous film with a low dielectric constant is to be formed on the surface of the workpiece, the resistance of the first variable resistor R1 can be increased, then the impedance of the RF current loop where the passive electrode 22 is located is increased and thus the current thereof will reduce. So, the effective area ratio of the passive electrode 22 to the RF driving electrode 25 (A₁/A₂) and the bias voltage at the RF driving electrode 25 will reduce accordingly, thus the plasma energy in the reaction chamber will be reduced.

Obviously, when the value of the resistance of the first variable resistor R1 reaches the maximum value, the plasma energy in the reaction chamber 21 can reach a minimum value. The minimum value which the plasma energy can reach could be changed by changing the maximum resistance of the first variable resistor R1.

A corresponding relationship between the plasma energy in the reaction chamber 21 and the resistance of the first variable resistor R1 can be established in advance. When the plasma energy in the reaction chamber 21 needs to change according to different technical processes requirements, a resistance of the first variable resistor R1 can be precisely selected based on the above mentioned corresponding relationship, so as to obtain plasma with an expected energy in the reaction chamber 21.

The plasma processing apparatus of the present invention employs a completely different idea to adjust the plasma energy in the reaction chamber 21. That is, in the present invention, the impedance of the loop, where the passive electrode 22 is located, is changed by adjusting the resistance of the first variable resistor R1, so as to change the current flowing through the passive electrode 22, thus changing the plasma energy in the reaction chamber 21.

The new idea provided by the present invention can adjust the magnitude of the RF current in the passive electrode 22 in a larger range. So the plasma processing apparatus provided by the present invention overcomes the above shortcoming that the plasma energy can only be switch among some certain isolated points, and can carry out more technical processes with different plasma density requirements in one and the same reaction chamber 21. The adaptability thereof is improved, and the matching of the reaction chamber 21 can be easily realized.

In addition, a resistor whose resistance can be continuously adjusted could be further selected as the first variable resistor R1. In this case, the current of the RF current loop where the passive electrode 22 is located can be changed continuously. So, it can be realized that the plasma energy in the reaction chamber 21 can be changed continuously. The adaptability of the plasma processing apparatus is further improved.

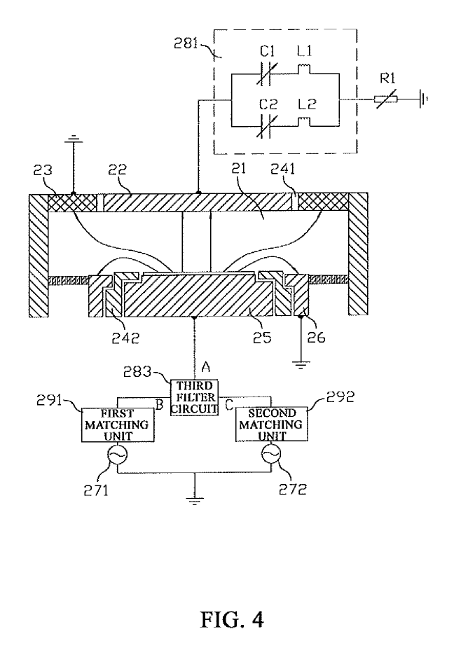

Reference is made to FIG. 4 which is a structural schematic diagram of a plasma processing apparatus according to a second embodiment of the present invention.

In the second embodiment, the plasma processing apparatus provided by this embodiment is made a further improvement on the basis of the first embodiment.

As mentioned above, in order to widen the adaptability of the plasma processing apparatus, parameters associated with plasma in the reaction chamber 21 should be able to be adjusted. The parameters usually involve the plasma density, the plasma energy, the plasma flow etc. The adjustment of the plasma energy is usually carried out by the first RF source 271; the adjustment of the plasma density is usually carried out by the second RF source 272.

When the above parameters are adjusted in order to adapt to different technical processes, it is better to control the plasma density and the plasma energy separately. However, it is difficult to realize the separate control of the plasma density and the plasma energy due to the coupling between the first RF source 271 and the second RF source 272.

In order to realize the decoupling between the first RF source 271 and the second RF source 272 so as to control the plasma density and the plasma energy separately, a first filter circuit 281 could be connected in series between the passive electrode 22 and the first variable resistor R1, or between the first variable resistor R1 and the ground. The pass band of the first filter circuit 281 should be able to be adjusted, and the range over which the band pass can be adjusted should at least cover the frequencies of the first RF source 271 and the second RF source 272, in order to select the RF current of at least one of two RF sources to flow through the passive electrode 22, or prevent the RF current of both the two RF sources from flowing through the passive electrode 22.

The band pass of the first filter circuit 281 can be adjusted so that it could become a low-pass filter. At this time, low-frequency current of the first RF source 271 can flow through the passive electrode 22, and high-frequency current of the second RF source 272 is prevented. At this time, the first grounded ring 23 and the second grounded ring 26 provide a loop for the high-frequency current of the second RF source 272.

Likewise, the band pass of the first filter circuit 281 can be adjusted so that it could become a high-pass filter. At this time, the high-frequency current of the second RF source 272 can flow through the passive electrode 22, and the low-frequency current of the first RF source 271 is prevented. At this time, the first grounded ring 23 and the second grounded ring 26 provide a loop for the low-frequency current of the first RF source 271.

Thus, the decoupling between the first RF source 271 and the second RF source 272 can be realized, and the high-frequency current and the low-frequency current will not interfere with each other any more. So, the plasma density and the plasma energy can be controlled separately.

As illustrated in FIG. 4, in a particular embodiment, the first filter circuit 281 of the present invention may comprise a first branch circuit and a second branch circuit which are connected in parallel. The first branch circuit consists of a first variable capacitor C1 and a first inductor L1 which are connected in series, and the second branch circuit consists of a second capacitor C2 and a second inductor L2 which are connected in series.

The resonance frequency of a circuit is f=(2π\sqrt{LC})⁻¹. So, when values of the first inductor L1 and the second inductor L2 are given respectively, ranges over which the first variable capacitor C1 and the second variable capacitor C2 change can be determined.

The first branch circuit is a low-frequency path. When it is required that the low-frequency current in the first RF source 271 should be selected to flow through the passive electrode 22, the first variable capacitor C1 can be adjusted so that the resonance frequency of the first branch circuit equals to the frequency of the first RF source 271.

The second branch circuit is a high-frequency path. When it is required that the high-frequency current in the second RF source 272 should be selected to flow through the passive electrode 22, the second variable capacitor C2 can be adjusted so that the resonance frequency of the second branch circuit equals to the frequency of the second RF source 272.

In the instant embodiment, the first filter circuit 281 uses two branch circuits, because the frequency of the first RF source 271 is greatly different from that of the second RF source 272 (in the instant embodiment, the latter is 30 times the former). As mentioned above, the resonance frequency is f=(2π\sqrt{LC})⁻¹, if the first filter circuit 281 comprises only one branch circuit, the variation range of the capacitor and the inductor is too broad. So it is better to use two branch circuits.

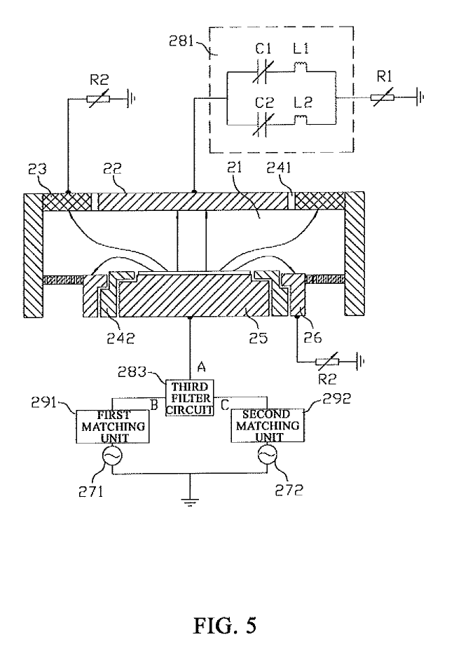

Now a reference is made to FIG. 5 which is a structural schematic diagram of a plasma processing apparatus according to the third embodiment of the present invention.

In the third embodiment, the plasma processing apparatus provided by this embodiment is made an improvement on the basis of the first and second embodiments.

In the first and second embodiments, the first grounded ring 23 and the second grounded ring 26 both are grounded directly. In the instant embodiment, a second variable resistor R2 as a second impedance adjusting element can be connected in series between the first grounded ring 23 and the ground, and/or between the second grounded ring 26 and the ground.

Similar to the above mentioned first variable resistor R1, the second variable resistor R2 can also be replaced by other impedance adjusting elements. For example, a resistor and a capacitor connected in series can be used as the above second impedance adjusting element.

The second variable resistor R2 is further set to adjust impedances of the current paths comprising the first grounded ring 23 and the second grounded ring 26, thus all impedances of respective current paths can be changed. So, the proportion of the current flowing through the passive electrode 22 can be adjusted in a larger range, the plasma energy in the reaction chamber 21 thus can be adjusted in a larger range too.

It should be pointed out that the above mentioned technical effect can be realized just by setting the second variable resistor R2 either between the first grounded ring 23 and the ground, or between the second grounded ring 26 and the ground. Of course, a better technical effect can be achieved by setting the second variable resistor R2 both between the first grounded ring 23 and the ground and between the second grounded ring 26 and the ground simultaneously.

In addition, a resistor whose resistance can be continuously changed could be further selected as the second variable resistor R2, so the plasma energy can be adjusted in a larger range.

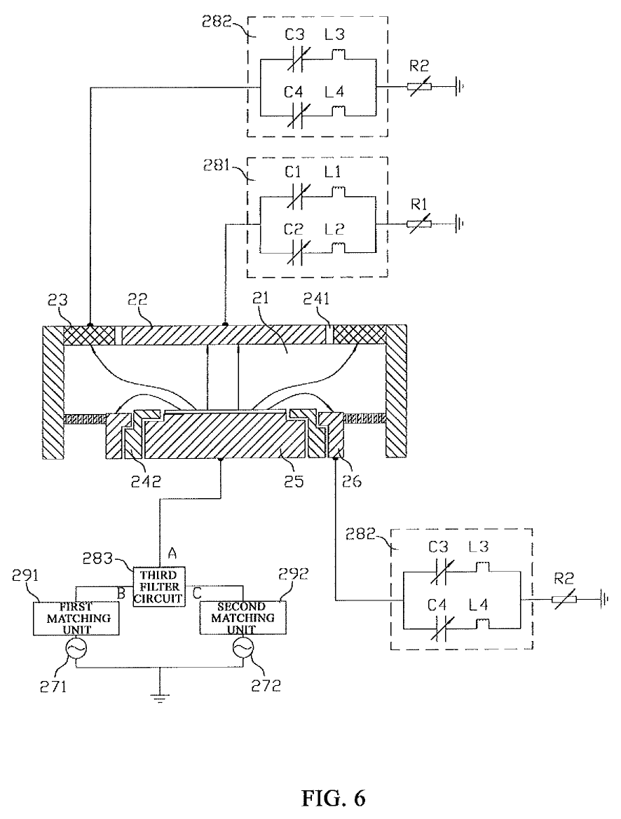

Please referring to FIG. 6, which is a structural schematic diagram of a plasma processing apparatus according to a fourth embodiment of the present invention.

In the fourth embodiment, the plasma processing apparatus is made an improvement on the basis of the above mentioned first to third embodiments.

As mentioned above, in order to realize the decoupling between the first RF source 271 and the second RF source 272, thus to realize controlling the plasma density and the plasma energy individually, the first filter circuit 281 can be connected in series between the passive electrode 22 and the first variable resistor R1, or between the first variable resistor R1 and the ground. This can realize the decoupling between the first RF source 271 and the second RF source 272. However, the decoupling cannot be realized completely. The reason is that the first grounded ring 23 and the second grounded ring 26 are grounded directly, or grounded through the resistors, so, there is always a part of the high-frequency current and the low-frequency current which can flow through the first grounded ring 23 and the second grounded ring 26 simultaneously.

In order to obtain a better technical effect so as to make the decoupling between the first RF source 271 and the second RF source 272 more complete, a second filter circuit 282 can be connected in series between the first grounded ring 23 and the ground, and between the second grounded ring 26 and the ground.

Similar to the first filter circuit 281, a pass band of the second filter circuit 282 should also be able to be adjusted, and the range over which the pass band is adjusted should cover at least the frequencies of the first RF source 271 and the second RF source 272, in order to select the RF current of at least one of the two RF sources to flow through the first grounded ring 23 and the second grounded ring 26, or to prevent both from flowing through the first grounded ring 23 and the second grounded ring 26.

The pass band of the first filter circuit 281 can be adjusted so that it could become a low-pass filter, and the pass band of the second filter circuit 282 is simultaneously adjusted so that it could become a high-pass filter. At this time, the low-frequency current of the first RF source 271 can flow through the passive electrode 22, and the high-frequency current of the second RF source 272 is prevented; while the high-frequency current of the second RF source 272 can flow through the first grounded ring 23 and the second grounded ring 26, and the low-frequency current of the first RF source 271 is prevented. In this case, in the reaction chamber 21, the plasma density is low and the plasma energy is high. Decoupling between the low-frequency current and the high-frequency current can be realized completely.

Likewise, the pass band of the first filter circuit 281 can be adjusted so that it could become a high-pass filter, and the pass band of the second filter circuit 282 is simultaneously adjusted so that it could become a low-pass filter. At this time, the low-frequency current of the first RE source 271 can flow through the first grounded ring 23 and the second grounded ring 26, and the high-frequency current of the second RF source 272 is prevented; while the high-frequency current of the second RF source 272 can flow through the passive electrode 22, and the low-frequency current of the first RF source 271 is prevented. In this case, in the reaction chamber 21, the plasma density is high and the plasma energy is low. Decoupling between the low-frequency current and the high-frequency current can also be realized completely.

Of course, it is also possible to connect the second filter circuit 282 in series only between one of the two grounded rings and the ground. However, this can only increase effect of the decoupling to a certain extent, and can't realize the decoupling completely.

In a particular embodiment, the second filter circuit 282 of the present invention may comprise a third branch circuit and a fourth branch circuit connected in parallel. The third branch circuit consists of a third variable capacitor C3 and a third inductor L3 connected in series; the fourth branch circuit consists of a fourth variable capacitor C4 and a fourth inductor L4 connected in series.

The reason that the second filter circuit 282 uses two branch circuits is the same as that for the first filter circuit 281, and will not be discussed here any more.

In order to increase the dissolution rate of ion so as to increase the plasma density, a method has arisen recently, in which a third RF source (the frequency of which is usually higher than 60 MHZ) is added besides the above mentioned first and second RF sources. It should be pointed out that the inventive concept and the technical solutions of the present invention also apply to this case.

In the above, the plasma processing apparatus provided by the present invention is described in detail. The principle of the present invention and its implementations are explained using illustrative examples, however, the above mentioned embodiments are only used to help understanding the method of the invention as well as its key concept. It should be pointed out that the persons skilled in the art could make many modifications and variants to the invention without departing from the principle of the present invention, and these modifications and variants are intended to be included within the scope as defined by the accompanying claims of the present invention.

1. A plasma processing apparatus, comprising: a RE driving electrode and a passive electrode mounted face to face; a first grounded ring surrounding the passive electrode and insulated from the passive electrode, a second grounded ring surrounding the RF driving electrode and insulated from the RF driving electrode; the RF driving electrode is connected with a first RF source and a second RF source respectively; characterized in that a first impedance adjusting element is connected in series between the passive electrode and the ground.

2. A plasma processing apparatus as claimed in claim 1, characterized in that impedance of the first impedance adjusting element is continuously adjustable.

3. A plasma processing apparatus as claimed in claim 2, characterized in that the first impedance adjusting element is a first variable resistor (R1); a first filter circuit connected in series with the first variable resistor (R1) is provided between the passive electrode and the ground; a pass band of the first filter circuit is adjustable, so as to select RF current of at least one of the first RF source and the second RF source to flow through, or select neither of RF current of the first RF source and the second RF source to flow through.

4. A plasma processing apparatus as claimed in claim 3, characterized in that the first filter circuit comprises a first branch circuit consisting of a first variable capacitor (C1) and a first inductor (L1) connected in series, and a second branch circuit consisting of a second variable capacitor (C2) and a second inductor (L2) connected in series; the first branch circuit and the second branch circuit are connected in parallel.

5. A plasma processing apparatus as claimed in claim 1, characterized in that a second impedance adjusting element is connected in series between the ground and at least one of the first grounded ring and the second grounded ring.

6. A plasma processing apparatus as claimed in claim 5, characterized in that impedance of the second impedance adjusting element is continuously adjustable.

7. A plasma processing apparatus as claimed in claim 6, characterized in that the second impedance adjusting element is a second variable resistor (R2); a second filter circuit is provided between the ground and the first grounded ring and/or the second grounded ring; the second filter circuit is connected in series with the second variable resistor (R2), and a pass band of the second filter circuit is adjustable, so as to select RF current of at least one of the first RF source and the second RF source to flow through, or select neither of RF current of the first RF source and the second RF source to flow through.

8. A plasma processing apparatus as claimed in claim 7, characterized in that the second filter circuit comprises a third branch circuit consisting of a third variable capacitor (C3) and a third inductor (L3) connected in series, and a fourth branch circuit consisting of a fourth variable capacitor (C4) and a fourth inductor (L4) connected in series; the third branch circuit and the fourth branch circuit are connected in parallel.

9. A plasma processing apparatus as claimed in claim 1, characterized in that the plasma processing apparatus is a plasma etching apparatus.

10. A plasma processing apparatus as claimed in claim 1, characterized in that the plasma processing apparatus is a plasma deposition apparatus.
